(19) United States
(12) Patent Application Publication
(10) Pub. No.: US 2021/0125906 A1
(43) Pub. Date: Apr. 29, 2021

(54) METAL ON MOLD COMPOUND IN FAN-OUT WAFER-LEVEL PACKAGING OF INTEGRATED CIRCUITS

(71) Applicant: SEMICONDUCTOR COMPONENTS INDUSTRIES, LLC, Phoenix, AZ (US)

(72) Inventor: Chia Hao KANG, Kaohsiung (TW)

(73) Assignee: SEMICONDUCTOR COMPONENTS INDUSTRIES, LLC, Phoenix, AZ (US)

(21) Appl. No.: 16/665,111

(22) Filed: Oct. 28, 2019

(51) Int. Cl. H01L 23/498; H01L 23/31; H01L 21/56; H01L 23/00

(52) U.S. Cl. CPC H01L 23/49816; H01L 23/3114; H01L 21/563; H01L 21/565; H01L 2224/11526; H01L 24/11; H01L 24/13; H01L 2224/02379; H01L 24/05

(57) ABSTRACT

A method includes disposing a patterned conductor layer directly on mold material in a fan-out space adjacent to an integrated circuit (IC) chip in a reconstituted wafer. The patterned conductor layer is limited or confined in spatial extent to the fan-out space. The method further includes configuring the patterned conductor layer disposed directly on mold material as a first redistribution layer (RDL) in a fan-out package of the IC chip to carry signals associated with at least one input-output (I/O) contact on the chip.

### TECHNICAL FIELD

This description relates to wafer-level packaging of integrated circuit devices.

### BACKGROUND

Fan-out wafer-level (FOWL) packaging (also known as wafer-level fan-out packaging, fan-out) is an integrated circuit (IC) packaging technology, and an enhancement of standard wafer-level packaging (WLP) solutions. In standard WLP packaging solutions, the ICs are packaged while still part of the wafer, and the wafer (with outer layers of packaging already attached) is diced afterwards; the resulting package is practically of the same size as the die (or chip) itself. However, the advantage of having a small package comes with a downside of limiting the number of external contacts that can be accommodated in the limited package footprint. This downside is a significant limitation with complex ICs requiring a large number of contacts. In contrast with standard WLP solutions, in fan-out WLP the wafer is diced first. The die (i.e., chips) are very precisely re-positioned on a carrier wafer or panel with space for fan-out maintained around each chip. The carrier wafer is then reconstituted by molding, followed by making a redistribution layer atop the carrier (extending over the chip and the adjacent fan-out area), and then forming solder balls on contacts pads on top.

### SUMMARY

In a general aspect, a method includes disposing a patterned conductor layer directly on a mold material in a fan-out space adjacent to an integrated circuit (IC) chip in a reconstituted wafer made of the mold material and the IC chip, The patterned conductor layer overlies the mold material of the reconstituted wafer in the fan-out space. The method further includes configuring the patterned conductor layer disposed directly on the mold material of the reconstituted wafer as a redistribution layer (RDL), the RDL layer being configured to carry a signal associated with at least one input-output (I/O) contact on the IC chip in a fan-out package of the IC chip.

In a general aspect, a package includes a reconstituted wafer made of a mold material and an IC chip. A patterned conductor layer overlies the mold material of the reconstituted wafer in a fan-out space lateral to the IC chip in the reconstituted wafer. The patterned conductor layer is configured as a redistribution layer (RDL) in the package of the IC chip to carry a signal associated with at least one input-output (I/O) contact on the IC chip.

In a general aspect, a package includes an integrated circuit (IC chip) disposed in a wafer made of mold material and a patterned conductor layer disposed directly on the mold material of the reconstituted wafer within a fan-out space adjacent to the IC chip in the wafer, the patterned conductor layer being a redistribution layer (RDL) disposed between the mold material of the reconstituted wafer and a stack of one or more additional RDLs interleaved with passivating layers. The patterned conductor layer is configured to carry a signal associated with at least one input-output (I/O) contact on the IC chip.

The details of one or more implementations are set forth in the accompanying drawings and the description below. Other features will be apparent from the description and drawings, and from the claims.

### BRIEF DESCRIPTION OF THE DRAWINGS

FIG. 1 illustrates an example multi-layer fan-out wafer-level package of an IC chip, in accordance with the principles of the present disclosure.

FIG. 2 illustrates an example method for packaging IC chips in a multi-layer fan-out wafer-level package, in accordance with the principles of the present disclosure.

FIGS. 3 through 6, FIGS. 7A, 7B, 8A and 8B, and FIGS. 9 through 14 illustrate views of an IC chip as it is being processed through multiple steps of an example packaging process to make a multi-layer fan-out wafer-level package, in accordance with the principles of the present disclosure.

### DETAILED DESCRIPTION

Modern integrated circuits (IC) (chips) that are fabricated with increasingly narrow input-output (I/O) pitch can have an increasing number of functions and a correspondingly increasing number of contacts that must be accommodated in fan-out wafer-level packages. Multiple redistribution layers (RDLs) (i.e., metallization levels) are needed for numerous conductor lines (e.g., metal connections) to carry signals for these functions to, and from, the I/O contacts on the chip. Processes for fabricating a fan-out wafer-level package with multiple RDLs become more and more complex as the number of RDLs increases. Each additional RDL layer requires a corresponding additional re-passivation layer (i.e., an insulating layer) for electrical isolation from other RDLs and the chip. Further, every additional RDL placed directly on top of the chip can aggravate quality issues in fabricating the multi-layer fan-out wafer-level package. The quality issues, may, for example, arise from film stress in the RDLs and the re-passivation layers caused by uneven surface topography of the chip.

The present disclosure describes a multi-layer fan-out wafer-level package in which a first RDL (e.g., a metal layer) is placed directly on mold material in a fan-out area adjacent to the chip on a carrier. While the first RDL extends over the mold material in the fan-out area, it does not extend over, or above, the chip itself. Placing the first RDL on (e.g., only on) the mold material (in other words, limiting or confining the RDL to the fan-out space) avoids the need for a re-passivation layer that would be required to separate or insulate the first RDL from the chip (e.g., as would be required if the first RDL was instead placed on, or over, the chip).

Further, the mold material in the fan-out space of the carrier is usually planarized. Placing the first RDL over the planar surface of the mold material in the fan-out space avoids, or at least reduces, stresses in the fan-out wafer-level package that can be caused by, for example, uneven surface topography of the chip (e.g., if the first RDL was instead placed on, or over, the chip).

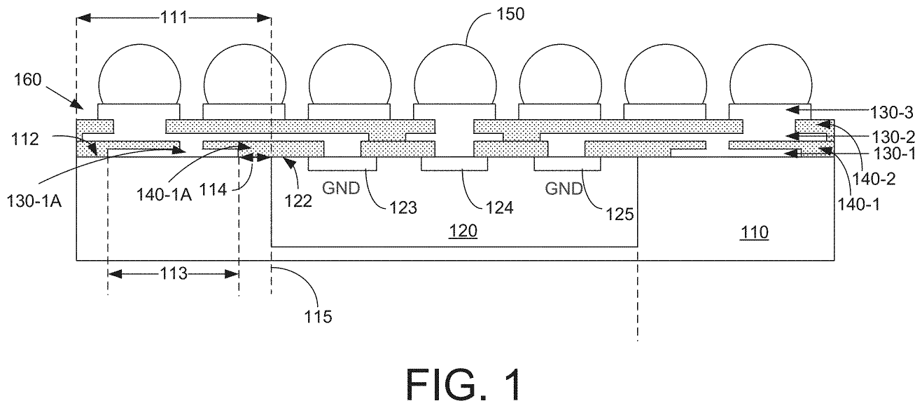

FIG. 1 shows a cross-sectional view of an example multi-layer (e.g., a 3-layer) fan-out wafer-level package 100 of an IC chip, in accordance with the principles of the present disclosure.

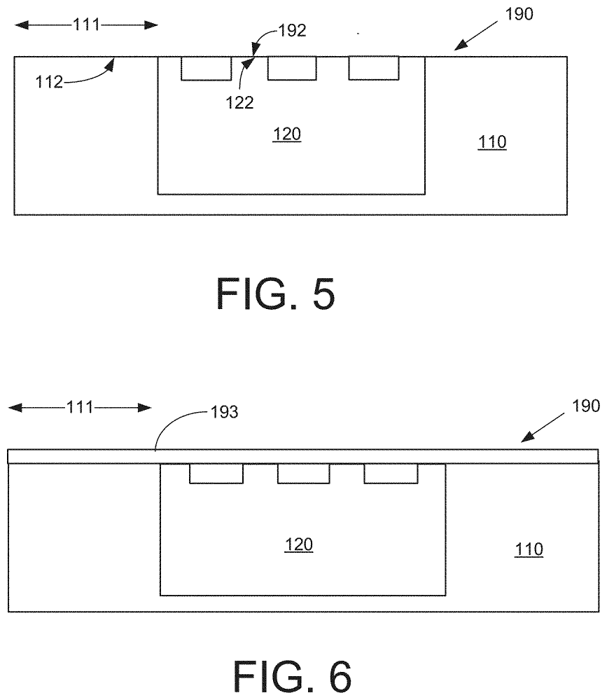

Package 100 may be fabricated from a planarized reconstituted wafer (e.g., reconstituted wafer 190, FIG. 5). The reconstituted wafer can made of mold material 110 in which integrated circuit chips (e.g., chips 120) are embedded (e.g., partially embedded). The mold material 110 of the reconstituted wafer can be referred to as was mold material. Chip 120 (also can be referred to semiconductor die) may have a top surface (e.g., surface 122, which can be referred to as an exposed top surface) in which conductive I/O contacts (e.g., contacts 123, 124, 125, etc.) are exposed. In other words, a top surface of the I/O contacts 123, 124, 125 can be co-planar with the surface 122. The I/O contacts (e.g., contacts 123, 124, 125, etc.) may correspond to different functions (e.g., a ground function, an input signal function, an output signal function, a reference function, a power function, etc.) of chip 120. Mold material 110 surrounding chip 120 may form a fan-out space 111 of the package. Mold material 110 may have a top surface 112 (e.g., an exposed top surface) in fan-out space 111 (which may be co-planar with top surface 122 of chip 120). A metallization structure 160 is disposed on chip 120 and mold material 110 disposed in adjacent fan-out space 111. Metallization structure 160 may include electrical conductor lines or traces for carrying (e.g., transmitting) signals between the chip I/O contacts (e.g., contacts 123-125) and a number of external contacts (e.g., solder bumps 150) including one or more external contacts distributed over fan-out space 111.

In the example shown in FIG. 1, metallization structure 160 includes three RDLs (i.e., RDL 130-1, RDL 130-2 and RDL 130-3) and only two re-passivation layers (i.e., layer 140-1, and layer 140-2). A first RDL (i.e., RDL 130-1) is placed (e.g., coupled) directly on only surface 112 of mold material 110 in fan-out space 111. RDL 130-1 may, for example, have a lateral size or spatial extent (e.g., extent 113) that is limited to be within fan-out space 111. The fan-out space 111 can terminate at an edge (e.g., edge 115) of the chip 120. RDL 130-1 is coupled directly to and only on surface 112 of mold material 110 in fan-out space 111. In other words, RDL 130-1 is coupled directly on surface 112 of mold material 110 in fan-out space 111 without an intervening layer (e.g., an insulating layer, etc.). Further, while surface 112 of mold material 110 may be co-planar with surface 122 of chip 120, RDL 130-1 because of its limited lateral size or spatial extent (e.g., extent 113) does not extend out from fan-out space 111 on to surface 122 of chip 120. There may be a gap (e.g., gap 114) between RDL 130-1 and an edge (e.g., edge 115) of chip 120 along surface 112 of mold material 110. In other words, RDL 130-1 placed directly on surface 112 of molding material 110 does not extend on to surface 122 and does not overlie or touch chip 120. Thus, a re-passivation layer isolating or separating chip 120 from RDL 130-1 is not needed.

In metallization structure 160, a first re-passivation layer (e.g., layer 140-1) separates the first RDL (i.e. RDL 130-1) from the second RDL (e.g., RDL 130-2), while a second re-passivation layer (e.g., layer 140-2) separates the second RDL (i.e. RDL 130-2) from the third RDL (e.g., RDL 130-3). The first re-passivation layer (e.g., layer 140-1) separates the first RDL (i.e. RDL 130-1) from the second RDL overlies (is directly coupled to and in contact with) RDL 130-1 within fan-out space 111 and overlies chip 120.

As shown in FIG. 1, a portion 140-1A of molding material 140-1 is disposed in gap 114 within the fan-out space 111 between a portion 130-1A of the RDL and an edge 115 of the chip 120. Portion 130-1A of the RDL overlies (e.g., is directly on, directly coupled to) the mold material 110 in the fan-out space 111. The portion 140-1A of the first re-passivation layer 140-1 may also overlie molding material 110 in the gap (e.g., gap 114) between RDL 130-1 and the edge (e.g., edge 115) of chip 120. However, since the first RDL (i.e., RDL 130-1) is placed only on surface 112 of mold material 110 in fan-out space 111 adjacent to chip 120 (i.e., not above chip 120) there is no need for an intervening passivation layer (e.g., an extra or additional re-passivation layer) directly above chip 120 to isolate it from RDL 130-1 (which would be needed if RDL 130-1 were disposed above chip 120).

In example implementations, the first RDL (i.e. RDL 130-1) may be a conductive film (e.g., a thin metallic film) that is deposited (e.g., by sputtering, evaporation, or electro-plating) on top surface 112 of mold material 110. Sputtered films and evaporated films, which can be thinner than plated films, may be used for applications that do not have high current requirements.

In example metallization structure 160, the first RDL (i.e., RDL 130-1) that is deposited on top surface 112 of mold material 110 can be used to connect all chip I/O contacts (e.g., contacts 123-125, etc.) that have a same function. For example, contact 123 and contact 125 may have a same function (e.g., a ground function). In this example, RDL 130-1 may be used to connect to contact 123 and contact 125.

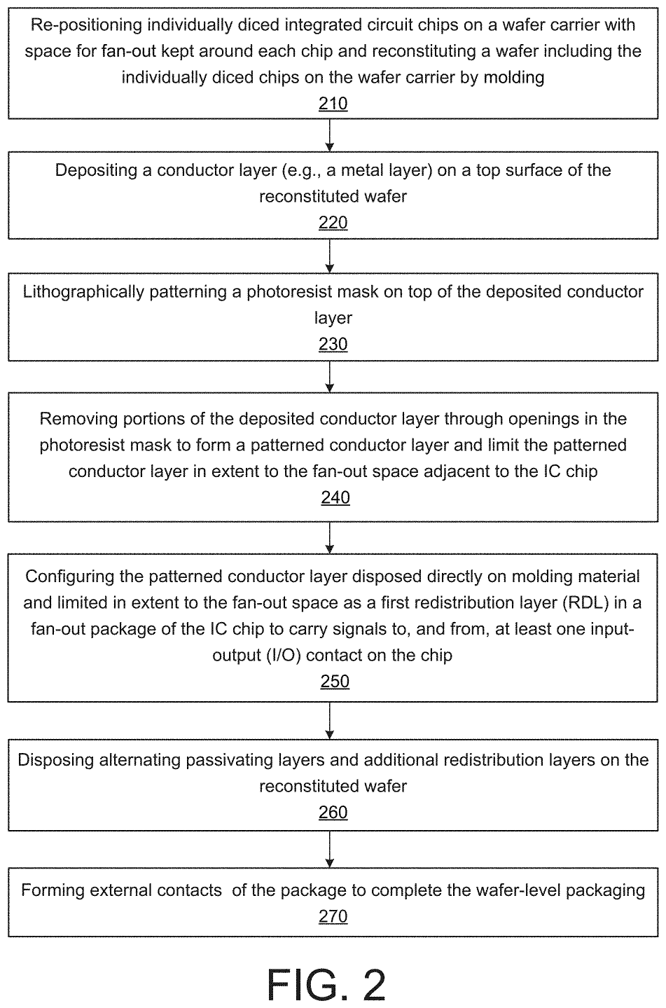

FIG. 2 illustrates an example method 200 for packaging IC chips 120 in a multi-layer fan-out wafer-level package (e.g., package 100), in accordance with the principles of the present disclosure.

Method 200 includes re-positioning individually diced IC chips (i.e., semiconductor die) on a wafer carrier with space for fan-out maintained around each chip, and reconstituting a wafer including the individually diced IC chips on the wafer carrier by molding (210). The molding material makes a fan-out area adjacent to each semiconductor die (chip) in the reconstituted wafer. I/O contacts of each chip may be exposed on a top surface of the chip, which is also a top surface of the reconstituted wafer. The top surface of the reconstituted wafer may be co-planar with a top surface of the molding material in the fan-out area.

Method 200 further includes depositing a conductor layer (e.g., a metal layer) on the top surface of the reconstituted wafer (220). The conductor layer (e.g., a metal) may be deposited (e.g., blanket deposited) over the top surface of the reconstituted wafer using, for example, sputtering, or evaporation techniques. An initially deposited conductor layer may be used as a seed layer for electroplating additional conductive material. The conductor layer may be a precursor of a first redistribution layer of the multi-layer fan-out wafer-level package (e.g., package 100).

For forming the first redistribution layer of the package, method 200 may next involve lithographic patterning of a photoresist mask on top of the conductor layer that has been deposited (e.g., blanket deposited) on the top surface of the reconstituted wafer (230); and removing portions of the blanket deposited conductor layer through openings in the photoresist mask to form a patterned conductor layer and limit the patterned conductor layer in spatial extent to the fan-out space adjacent to the IC chip (240). In other words, the patterned conductor layer spatially extends only over molding material adjacent to a semiconductor die (chip) in the reconstituted wafer but does not touch or overlie the IC chip. The patterned conductor layer is not buried in the molding material but overlies the molding material adjacent to the semiconductor die (chip) in the reconstituted wafer and is limited in spatial extent to be within the fan-out space.

Method 200 also includes configuring the patterned conductor layer as a first redistribution layer (RDL) in the fan-out package of the IC chip to carry signals to, and from, at least one input-output (I/O) contact on the chip (250).

Method 200 further includes disposing alternating passivating layers and additional redistribution layers (e.g., a second redistributing layer and a third redistribution layer) (260). Method 200 also includes forming external contacts of the package to complete the wafer-level packaging (270). The external contacts may be solder balls. Forming the external contacts may include forming an under-bump metallization (UBM) structure in contact with the last RDL (e.g., the third redistribution layer) followed solder ball drop to complete the wafer-level -package.

FIGS. 3 through 6, FIGS. 7A, 7B, 8A and 8B, and FIGS. 9 through 14 illustrate views of an IC chip (e.g., chip 120) as it is being processed through multiple steps of an example packaging process to make a multi-layer fan-out wafer-level package (e.g., package 100, FIG. 1), in accordance with the principles of the present disclosure. While like reference characters or numerals are used to label like elements throughout the various drawings, some of the elements are not labeled in some of the figures for visual clarity in views and simplicity in description.

Chip 120 may be an integrated circuit fabricated on a semiconductor wafer (not shown), for example, in semiconductor device fabrication facility. The semiconductor wafer may be processed up to a final metallization stage for making I/O contact pads (e.g., contacts 123-125, etc.) on a top surface (e.g., surface 122) of chip 120. The semiconductor wafer may be then diced, and chips 120 may be retrieved, for example, as individual semiconductor die.

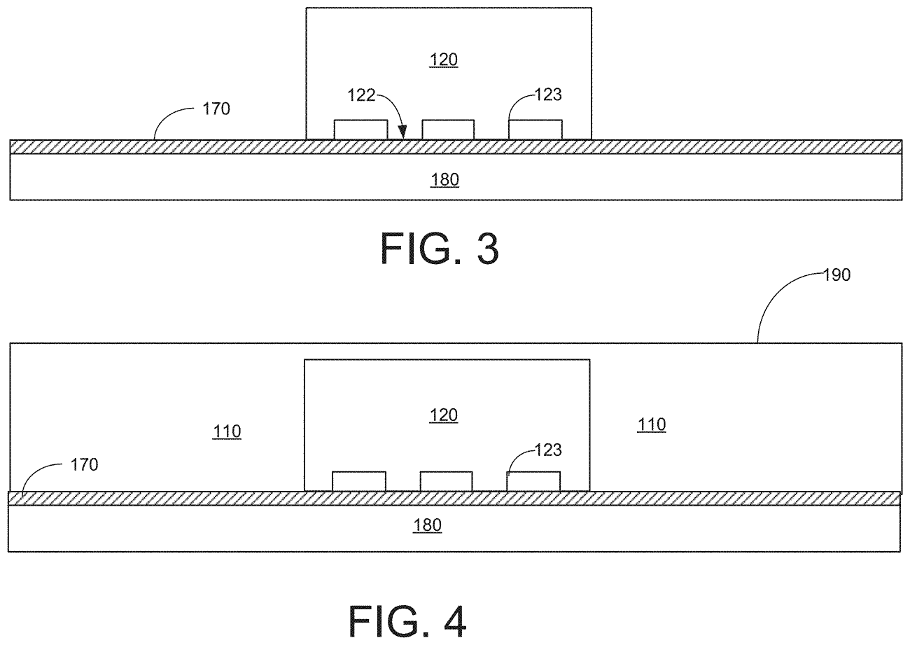

FIG. 3 and FIG. 4 schematically show a wafer-reconstitution process for making a reconstituted wafer (e.g., reconstituted wafer 190, FIG. 5) from the individual semiconductor die (e.g., chips 120). As shown in FIG. 3, a wafer carrier 180 may be lined with a mold release film 170. Individual chips 120 with top surface 122 facing down (i.e., toward mold release film 170) are repositioned on mold release film 170 on wafer carrier 180. The repositioned individual chips may be spaced apart from each other to create space for a fan-out area about each chip. Next, as shown in FIG. 4, a molding compound (e.g., an epoxy) may be used to encase individual chips 120 positioned on the carrier and to, thus, form a reconstituted wafer 190. By activating mold release film 170, reconstituted wafer 190 may be lifted or released from the underlying wafer carrier 180 as a standalone unit. FIG. 5 shows an example reconstituted wafer 190 as a standalone unit that may be used in wafer-level packaging processes (e.g., by method 200) for packaging chips 120. Reconstituted wafer 190 may have a top surface 192 that includes top surface 122 of chip 120 and top surface 112 of mold material 110 in fan-out space 111 adjacent to chips 120.

As shown in FIGS. 6-13, wafer-level processing of reconstituted wafer 190 can be used to fabricate a multi-layer fan-out wafer-level package (e.g., package 100) of chips 120. The wafer-level processing steps may, for example, correspond to the steps of method 200 described above with reference to FIG. 2.

FIG. 6 shows a conductor layer 193 that is deposited (e.g., blanket deposited) on top surface 192 of reconstituted wafer 190 (e.g., at step 220 of method 200). In example implementations, conductor layer 193 may be made of a conductive material (e.g., copper, aluminum, metal alloys, etc.). Conductor layer 193 may be blanket deposited on top surface 192 of reconstituted wafer 190 using, for example, evaporation or sputtering techniques. As shown in FIG. 6, conductor layer 193 may extend over all of the top surface of the reconstituted wafer including over chips 120 and over fan-out space 111 adjacent to chips 120. Conductor layer 193 may provide a starting material for a first redistribution layer of package 100.

In some implementations, the first redistribution layer may be formed by lithographic patterning of the evaporated or sputtered conductive material of conductor layer 193.

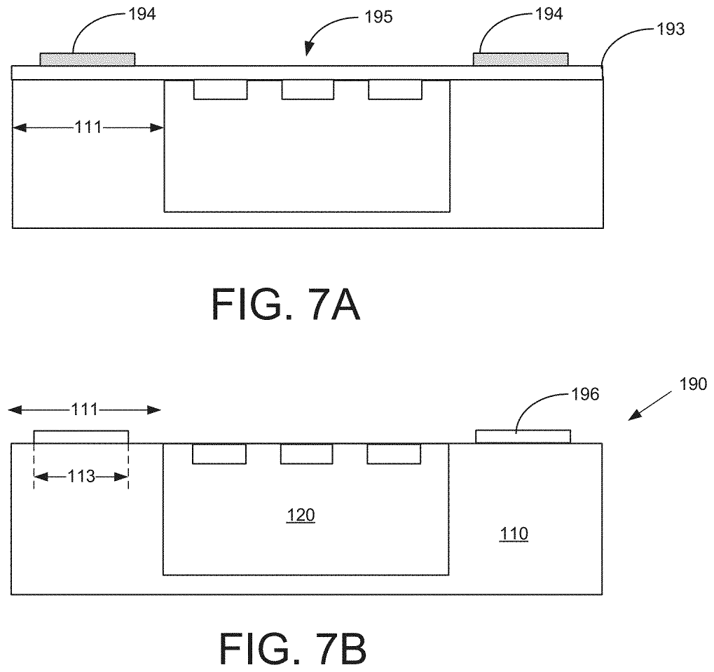

FIG. 7A shows a lithographically patterned photoresist mask layer 194 deposited on conductor layer 193 (e.g., at step 230 of method 200). Photoresist mask layer 194 may include a pattern with openings 195 that expose portions of underlying conductor layer 193.

Next, FIG. 7B shows a patterned conductor layer 196 obtained by removing (e.g., etching) exposed portions of conductor layer 193 according to the pattern of photoresist mask layer. In example implementations, patterned conductor layer 196 may be obtained, for example, etching through openings 195 in photoresist mask layer 194 (e.g. ,at step 240 of method 200).

In some implementations, the evaporated or sputtered conductive material of conductor layer 193 may be used as a seed layer for electroplating additional conductive material to form the first redistribution layer.

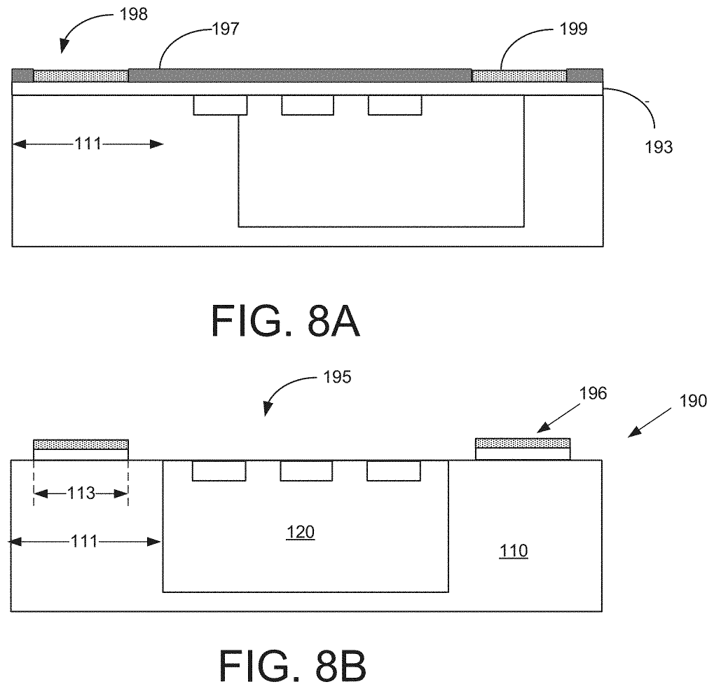

FIG. 8A shows a lithographically patterned photoresist mask layer 197 deposited on conductor layer 193 (e.g., at step 230 of method 200). Photoresist mask layer 197 may include a pattern with openings 198 that expose portions of underlying conductor layer 193 that are used as seed layer for electroplating additional conductive material 199.

Next, FIG. 8B shows patterned conductor layer 196 obtained by removing (e.g., photoresist stripping) photoresist mask layer 197 and removing (e.g., etching) the newly exposed (re-exposed) portions of conductor layer 193 (i.e., portions of conductor layer 193 through openings 195 that are not masked by the pattern of additional conductive material 199).

As shown in FIG. 7B and FIG. 8B, patterned conductor layer 196 extends over molding material 110 in fan-out area 111 adjacent to chip 120 and forms the first redistribution layer (e.g., RDL 130-1) of package 100. Patterned conductor layer 196 has a small size or spatial extent (e.g., extent 113) so that it is contained within fan-out space 111 adjacent to chip 120 and does not touch or overlie chip 120.

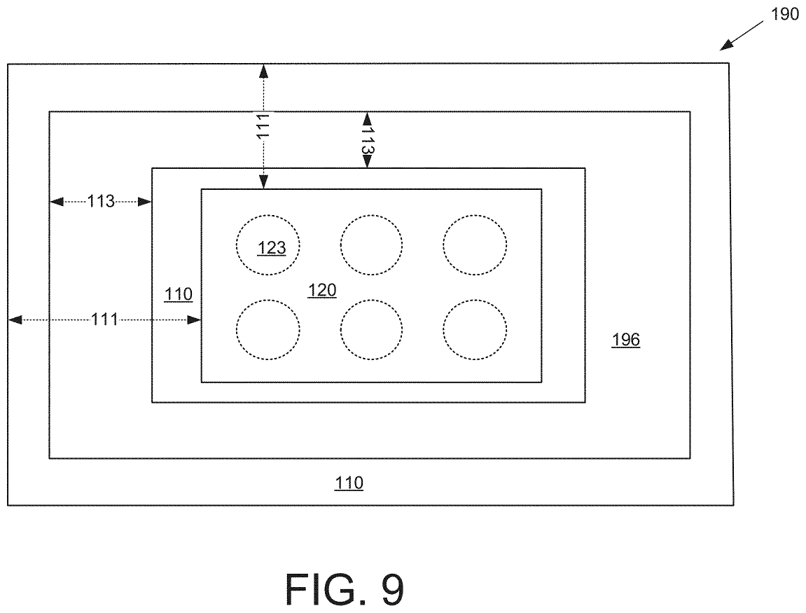

Patterned conductor layer 196 may be configured (e.g., shaped or patterned) to serve as the first redistribution layer (RDL) to carry signals to, and from, at least one I/O contact on the chip in the fan-out package of the IC chip (at step 250 of method 200). A shape or pattern of patterned conductor layer 196 is defined, for example, by a layout of openings 195 in patterned photoresist mask layer 194 (FIG. 7). FIG. 9 shows (in plan view) patterned conductor layer 196 as having an example annular shape (e.g., of an annular rectangle) in fan-out space 111surrounding chip 120. In example implementations of package 100, patterned conductor layer 196 as having the example shape of an annular rectangle can be used to connect to all chip I/O contacts having a same function.

By using different layouts of openings 195 in patterned photoresist mask layer 194, different shapes or patterns of patterned conductor layer 196 in fan-out space 111 surrounding chip 120 can be obtained. The different shapes or patterns of patterned conductor layer 196 may include any kind of geometrical shape (e.g., wide area or trace).

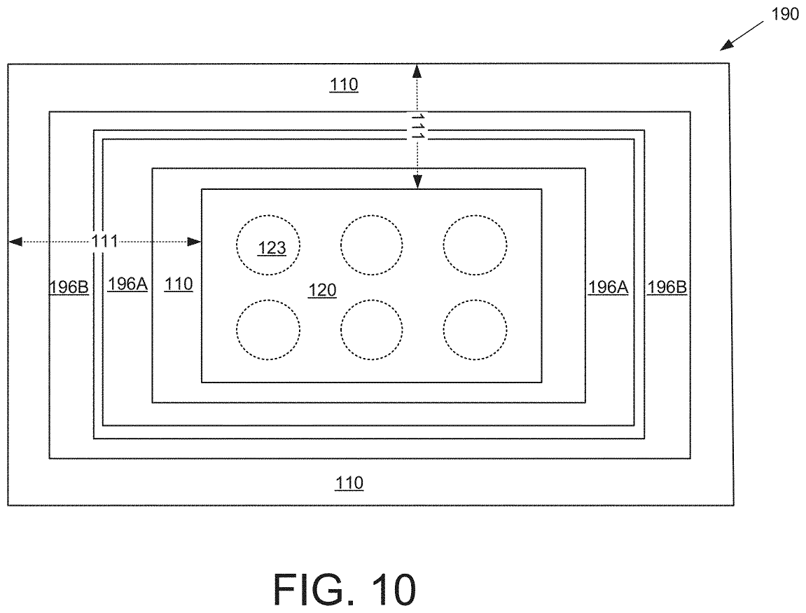

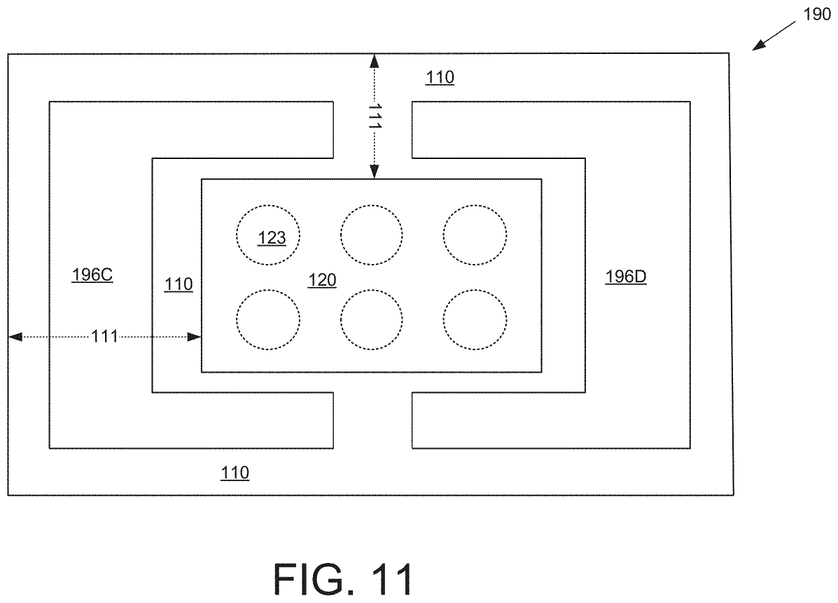

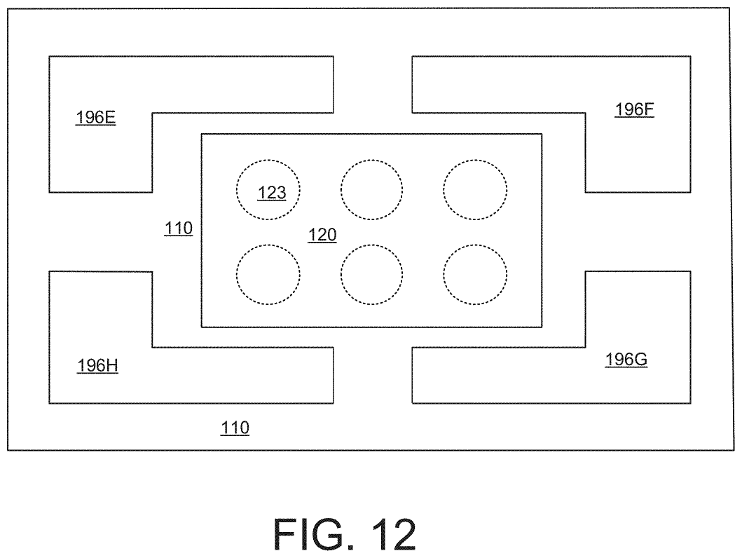

FIG. 10, FIG. 11, and FIG. 12 show examples of the different shapes of patterned conductor layer 196 that may be used as the first redistribution layer in package 100. FIG. 10 shows, for example, patterned conductor layer 196 having an annular shape including two disjoint annular rectangular shape sections (e.g., sections 196A and 196B) in fan-out space 111 around chip 120. FIG. 11 shows, for example, patterned conductor layer 196 having an annular rectangular shape including two disjoint C-shape sections (e.g., sections 196C and 196D) in fan-out space 111 around chip 120. FIG. 12 shows, for example, patterned conductor layer 196 having an annular rectangular shape including four disjoint L-shape sections (e.g., sections 196E, 196F. 196G, and 196H) in fan-out space 111 around chip 120. In example implementations of package 100, each of the disjoint sections in a patterned conductor layer 196 may be connected to I/O contacts (e.g., contacts 123-125, etc.) having a same function. For example, with reference to FIG.11, section 196C may be connected to contacts 123 and 125 having a same first function (e.g., a ground function) and section 196D may be connected to contact 124 having a second function (e.g., an input signal function).

Further, the wafer-level processing steps to make the multi-layer fan-out wafer-level package (e.g., package 100) of chips 120 may include forming alternating additional passivating layers and additional RDLs (e.g., at step 260 of method 200) to complete metallization structure 160 on the reconstituted wafer 190.

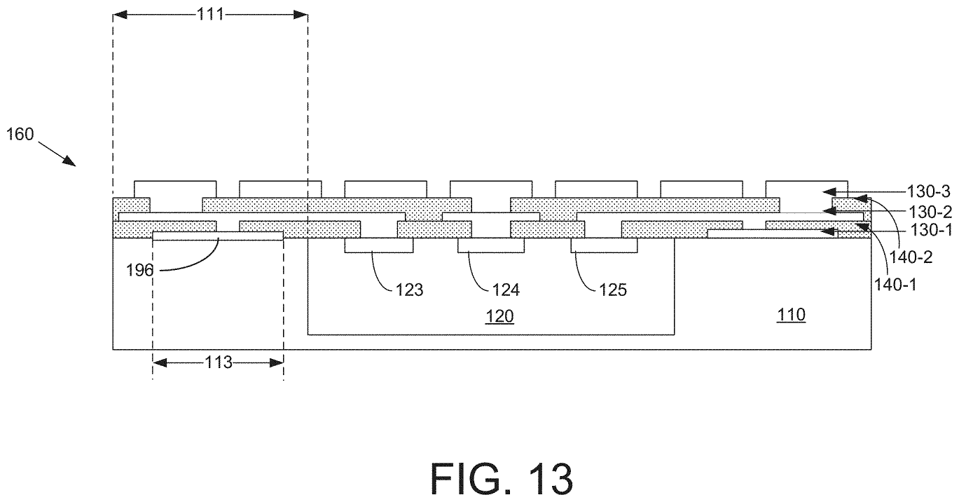

FIG. 13 shows, for example, two additional passivating layers (e.g., layers 140-1 and 140-2) and two additional distribution layers (e.g., RDL 130-2 and 130-3) formed above conductor layer 196 that forms the first distribution layer (e.g., RDL 130-1) on the reconstituted wafer 190. The additional passivating layers (e.g., layers 140-1 and 140-2) may be made by photo-lithographic processes using materials that are imageable. The materials used may, for example include polymers (e.g., a polyimide, polybenzobisoxazole (PBO), photo imageable solder masks, etc.) and epoxy. The additional distribution layers (e.g., RDL 130-2 and 130-3) may be made of conductive materials (e.g., copper, aluminum, metal alloys, etc.) using material deposition techniques (e.g., evaporation, sputtering, or electroplating) and lithographic patterning techniques that are the same as, or similar to, the techniques described above (e.g., with reference to FIGS. 3-12) for fabricating patterned conductor layer 196 that forms the first distribution layer (e.g., RDL 130-1).

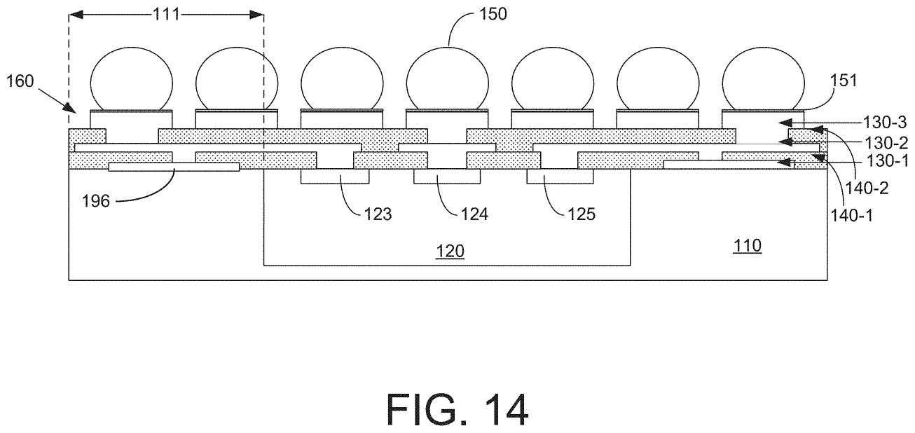

Additional wafer-level processing steps (e.g., at step 270 of method 200) to complete the multi-layer fan-out wafer-level package (e.g., package 100) of chips 120 may include forming external contacts (e.g., solder balls 150) of package 100. As shown in FIG. 14, solder balls 150 may provide external contacts on package 100 for signals that are routed via the various redistribution layers (including RDL 130-1) to, and from chip I/O contacts (e.g., contacts 123-125, etc.). Forming the external contacts may include forming under-bump metallization (UBM) structures 151 followed by solder ball drop (e.g., solder ball 150).

After the external contacts (e.g., solder balls) are formed on reconstituted wafer 190, wafer 190 may be singulated or diced (not shown) to retrieve individual multi-layer packages of individual chips 120.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A method, comprising:
disposing a patterned conductor layer directly on a mold material in a fan-out space adjacent to an integrated circuit (IC) chip in a reconstituted wafer made of the mold material and the IC chip, the patterned conductor layer overlying the mold material of the reconstituted wafer in the fan-out space; and
configuring the patterned conductor layer disposed directly on the mold material of the reconstituted wafer as a redistribution layer (RDL), the RDL layer being configured to carry signal associated with at least one input-output (I/O) contact on the IC chip in a fan-out package of the IC chip.

2. The method of claim 1, wherein the disposing the patterned conductor layer directly on mold material of the reconstituted wafer in a fan-out space adjacent to an integrated circuit (IC) chip in a reconstituted wafer includes:
depositing a conductor layer on a top surface of the reconstituted wafer;
lithographically patterning a photoresist mask on top of the blanket deposited conductor layer; and
removing portions of the deposited conductor layer through openings in the photoresist mask to form the patterned conductor layer and limit the patterned conductor layer to be within the fan-out space adjacent to the IC chip.

3. The method of claim 2, further comprising:
disposing alternating passivating layers and additional RDLs on the reconstituted wafer to form the fan-out package of the IC chip.

4. The method of claim 3, further comprising:
forming an external contact of the package.

5. The method of claim 4, wherein forming the external contact of the package includes: forming an under metal bump (UMB) structure and a solder ball drop.

6. The method of claim 2, wherein the depositing the conductor layer on the top surface of the reconstituted wafer includes:
depositing conductive material by at least one of sputtering, evaporation or electroplating.

7. The method of claim 2, wherein removing portions of the deposited conductor layer through openings in the photoresist mask includes etching the portions of the deposited conductor layer through the openings.

8. The method of claim 2, wherein configuring the patterned conductor layer disposed directly on mold material of the reconstituted wafer as a first redistribution layer (RDL) includes:
forming the patterned conductor layer to have an annular shape in the fan-out space surrounding the chip.

9. The method of claim 8, wherein the annular shape in the fan-out space includes two disjoint annular shapes in the fan-out space.

10. The method of claim 8, wherein the annular shape in the fan-out space includes two disjoint C-shape sections.

11. The method of claim 8, wherein the annular shape in the fan-out space includes four disjoint L-shape sections.

12. A package, comprising:
a reconstituted wafer made of a mold material and an IC chip;
a patterned conductor layer overlying the mold material of the reconstituted wafer in a fan-out space lateral to the IC chip in the reconstituted wafer,
the patterned conductor layer being configured as a redistribution layer (RDL) in the package of the IC chip, the RDL layer being configured to carry a signal associated with at least one input-output (I/O) contact on the IC chip.

13. The package of claim 12, further comprising:
alternating passivating layers and additional RDLs disposed on the reconstituted wafer above the patterned conductor layer and the IC chip.

14. The package of claim 12, further comprising a plurality of external contacts including at least an under-metal bump (UMB) structure and a solder ball.

15. The package of claim 12, wherein the patterned conductor layer includes at least one of sputtered, evaporated or electroplated conductive material.

16. The package of claim 12, wherein the patterned conductor layer has an annular shape in the fan-out space surrounding the chip.

17. The package of claim 16, wherein the annular shape in the fan-out space includes at least two disjoint annular shapes in the fan-out space.

18. The package of claim 16, wherein the annular shape in the fan-out space includes at least two disjoint C-shape sections.

19. The package of claim 16, wherein the annular shape in the fan-out space includes at least four disjoint L-shape sections.

20. A package, comprising:
an integrated circuit (IC chip) disposed in a wafer made of mold material;
a patterned conductor layer disposed directly on the mold material of the reconstituted wafer within a fan-out space adjacent to the IC chip in the wafer,
the patterned conductor layer being a redistribution layer (RDL) disposed between the mold material of the reconstituted wafer and a stack of one or more additional RDLs interleaved with passivating layers, the patterned conductor layer being configured to carry a signal associated with at least one input-output (I/O) contact on the IC chip.
